(19) United States
(12) Patent Application Publication
(10) Pub. No.: US 2026/0063418 A1
(43) Pub. Date: Mar. 5, 2026

(54) AUTOMATIC COMPUTER-IMPLEMENTED DETECTION OF SPOT DEFORMATION

(71) Applicant: Applied Materials Israel Ltd., Rehovot (IL)

(72) Inventors: Einat FRISHMAN, Rehovot (IL); Gadi ORON, Rehovot (IL); Idan Avraham TAMIR, Herzliya (IL)

(21) Appl. No.: 19/316,912

(22) Filed: Sep. 2, 2025

(30) Foreign Application Priority Data
Sep. 2, 2024 (IL) 315400

(51) Int. Cl. G01B 15/06; G06T 5/70; G06T 7/00

(52) U.S. Cl. CPC G01B 15/06; G06T 5/70; G06T 7/0004; G06T 2207/10024; G06T 2207/10061; G06T 2207/30148; G06T 2207/30168

(57) ABSTRACT

The presently disclosed subject matter includes a computer system and a computer-implemented method for detecting spot deformation in focused charged particle beam devices.

### TECHNICAL FIELD

The presently disclosed subject matter is related to detection of deformation in a spot of focused charged particles beam devices.

### BACKGROUND

Focused charged particle beam devices (FCPB devices), such as Scanning Electron Microscopes (SEM), Transmission Electron Microscopes (TEM), Focused Ion Beam (FIB) systems, and Scanning Transmission Electron Microscopes (sTEM), are important tools in various industries for characterization and quality control of intricate structures. These devices are indispensable in fields such as materials science, nanotechnology, and biology.

The precision of imaging with focused charged particle beam devices is fundamentally dependent on the quality of the particle beam spot, which must be small, round, and symmetric, to ensure high-resolution images with minimal distortion. Maintaining a well-defined spot is essential for obtaining reliable measurements, detecting defects, and ensuring device performance in various applications.

Astigmatism and other aberrations that result in the deformation of a spot's shape, can introduce errors in the imaging process, leading to inaccurate representations of the observed features. These deviations can compromise the integrity of the data obtained, degrading its quality and the ability to analyze and extract the required information. Therefore, correcting astigmatism and other spot aberrations is essential to maintain the accuracy and reliability of imaging data.

In the semiconductor industry, such tools play a critical role in the accurate characterization and quality control of intricate microelectronic structures, such as wafers and dies. Deformation of the spot's shape can negatively affect the development and manufacturing of microelectronic devices.

### GENERAL DESCRIPTION

According to a first aspect of the presently disclosed subject matter there is provided a computer-implemented method of detecting spot deformation in a Focused
Charged Particles Beam (FCPB) device, comprising:

obtaining an image of a circular feature of a specimen (e.g., semiconductor specimen) generated by the FCPB device while defocused; detecting radial aberration lines in the image; comparing between summed intensities of the radial aberration lines to determine irregularities; and assessing a degree of spot deformation based on the irregularities.

In addition to the above features, the method according to this aspect of the presently disclosed subject matter can optionally comprise one or more of features (i) to (x) below, in any desired and technically possible combination or permutation:
i. Wherein the image includes a circular donut-like shape with an inner circular region bounded by a circumference, the inner circular region and the circumference being rendered in contrasting colors, with one being lighter than the other (e.g., dark inner circle and lighter circumference); wherein detecting radial aberration lines comprises: unwrapping the circular donut-like shape, thereby transforming the radial aberration lines into a plurality of straight (e.g., diagonal) lines uniformly projected onto Cartesian coordinates.
ii. Wherein the comparing between summed intensities of the radial aberration lines comprises: applying autocorrelation on the radial aberration lines and detecting periodic peaks that indicate respective periodic irregularities in the image; wherein a greater amplitude of the peaks correlates with a greater respective irregularity, indicating deformation of the spot shape.
iii. Wherein the comparing between summed intensities of the radial aberration lines comprises: applying autocorrelation on the plurality of straight (e.g., diagonal) lines and detecting periodic peaks that indicate respective periodic irregularities in the image; wherein a greater amplitude of the peaks correlates with a greater respective irregularity, indicating deformation of the spot shape.
iv. Wherein the feature is a contact hole.
v. Wherein the method comprises determining a centroid of the donut-like shape prior to unwrapping of the donut-like shape.
vi. Wherein the method comprises applying one or more denoising processes on the image and/or its derivatives.
vii. Wherein the method comprises generating the image by scanning the feature while a scanning beam/lens of the FCPB device is defocused.
viii. Wherein assessing the degree of spot deformation comprises: calculating a score based on a difference between high autocorrelation peak values and low autocorrelation trough values, wherein higher scores are correlated with more significant deformation of the spot shape.
ix. Wherein the FCPB device is a Scanning Electron Microscope (SEM).
x. Wherein the FCPB device is any one of: Transmission Electron Microscopes (TEM), Focused Ion Beam (FIB) systems, and Scanning Transmission Electron Microscopes (sTEM).

According to a second aspect of the presently disclosed subject matter there is provided a computer system configured and operable to detect spot deformation in a Focused Charged Particles Beam (FCPB) device, the system comprising at least one processing circuitry configured to execute the method according to the first aspect above.

According to a third aspect of the presently disclosed subject matter there is provided a non-transitory computer readable medium comprising instructions that, when executed by a computer, cause the computer to perform a computer-implemented method of detecting spot deformation in a Focused Charged Particles Beam (FCPB) device according to the first aspect above.

According to a fourth aspect of the presently disclosed subject matter there is provided an examination system dedicated for analyzing semiconductor specimens as part of a semiconductor manufacturing process, the system comprising, or is otherwise operatively connected to a Focused Charged Particles Beam (FCPB) device (e.g., SEM) and to at least one processing circuitry configured to execute a computer-implemented method of detecting spot aberrations in the Focused Charged Particles Beam (FCPB) device according to the first aspect above.

The method, the systems, and the non-transitory program storage device, disclosed with reference to the second, third, and fourth aspects, can optionally comprise one or more of features (i) to (x) listed above, mutatis mutandis, in any technically possible combination or permutation.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIG. 1 illustrates a generalized block diagram of an examination system, in accordance with certain examples of the presently disclosed subject matter;

FIG. 2 illustrates a block diagram of a spot deformation detection module, in accordance with certain examples of the presently disclosed subject matter;

FIG. 3a is a high-level flowchart showing principal operations carried out as part of spot deformation detection process, in accordance with certain examples of the presently disclosed subject matter;

FIG. 3b is a flowchart showing a more detailed example of the spot deformation detection process;

FIG. 4 shows six images A to F of a SEM image of a contact hole acquired in defocused mode according to an example;

FIG. 5 shows the six images following denoising according to an example;

FIG. 6 shows the six images following unwrapping according to an example;

FIG. 7 shows the six images following further denoising according to an example;

FIG. 8 shows the six images following further sharpening according to an example; and

FIGS. 9a to 9d show each of the six respective plots, each plot corresponding to the autocorrelation output of a given image according to an example.

FIG. 10 shows examples of images of contact holes that can be used in the spot deformation detection process.

### DETAILED DESCRIPTION

As mentioned above, for focused charged particle beam devices, achieving a small, round, and symmetric electron beam spot is essential for high-resolution imaging. Optimal performance during scanning requires the most symmetrical and smallest possible spot size. However, various influencing factors can cause the spot to deviate from its ideal shape, resulting in variations such as elliptical or triangular spots.

When scanning a sample (e.g., a semiconductor specimen) with a FCPB device, the resulting image is practically a convolution of the sample's pattern with the shape of the spot. If the spot is not perfectly circular (i.e., is “deformed”), this convolution process results in a sub-optimal final output image. These errors manifest as various types of distortions and inaccuracies, compromising the quality and reliability of the scanned images, degrading the ability to extract meaningful information from these images.

Errors in the FCPB device spot are often identified when the same sample is scanned by different tools of the same type, and discrepancies between the outputs are observed in a process commonly known as “matching”. In the context of SEM, “matching” involves calibrating and aligning multiple SEM tools to achieve consistent and reproducible scanning results across the same sample. Ensuring accurate matching is important for quality control and process reliability, as it guarantees that measurements and inspections conducted with different SEM tools produce comparable outputs. If discrepancies are found during a matching process, detailed investigation may reveal that the root cause is that the electron beam spot from one tool is not perfectly round.

The continuously decreasing allowable error margin, driven by increasing client demands for precision, presents significant challenges due to the nanometer-scale size of the spot, making detection and correction of aberrations difficult.

Detection of spot aberrations often relies on human reviewers who manually inspect defocused images and search for patterns commonly resulting from spot deformation. This method is problematic due to the inherent inconsistencies and inaccuracies of human judgment. Additionally, training human reviewers to accurately identify these aberrations is time-consuming and requires extensive experience, which further complicates the process. Furthermore, the availability of images can be a limiting factor if not provided by the semiconductor manufacturers. Some existing software tools dedicated for spot deformation detection are processing intensive and limited in their ability to detect higher order aberrations.

The presently disclosed subject matter includes a computer system and a computer-implemented method for detecting spot deformation in focused charged particle beam devices. Unlike the use of human reviewers, this approach provides automated, consistent, and accurate detection of such spot aberrations, enhancing the overall reliability of the FCPB device imaging process. In the semiconductor industry this enables meeting high precision demands. It is a ready-to-use solution that does not require extensive gathering of training data and training, as is necessary with machine learning models, nor does it require the lengthy and cumbersome training of human reviewers.

It is noted that while the following description predominantly pertains to Scanning Electron Microscopes (SEM) and semiconductors, this focus is provided by way of example only, for ease of understanding. The concepts, methods, and applications discussed herein are not limited to SEM and semiconductor technology, and are likewise applicable to a broad range of focused charged particle beam devices, and can be utilized in various other fields and industries. This includes, but is not limited to, materials science, nanotechnology, biology, and any other area where precise characterization and quality control of intricate structures are required.

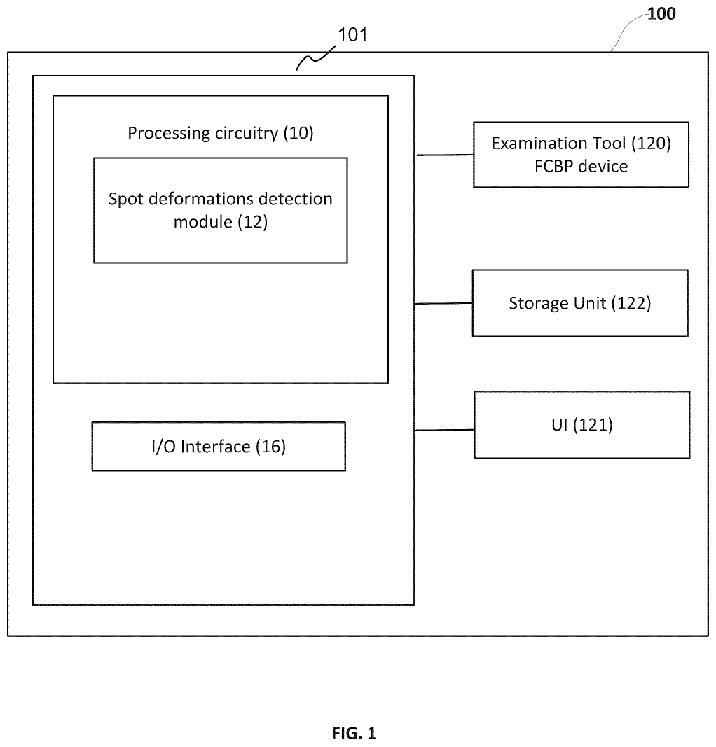

Bearing the above in mind, attention is drawn to FIG. 1, which is a generalized block diagram illustration of a computer system 101 configured with automatic spot deformation detection capabilities according to examples of the presently disclosed subject matter. FIG. 1 shows a non-limiting example where system 101 is integrated in a semiconductor examination system 100. In other examples system 101 and 100 can be separated, possibly located at different locations, and be operatively connectible over a communication link.

Examination system 100 can be used for examination of a semiconductor specimen (e.g., a wafer, a die, or parts thereof) e.g., as part of the specimen fabrication process. The examination referred to herein can be construed to include any kind of operations related to inspection of semiconductor specimens, including the inspection/detection of defects, defect classification, segmentation, metrology operations, etc., with respect to the specimen. System 100 can comprise one or more examination tools 120 configured to scan a specimen and capture images thereof to be further processed for various examination applications.

The term “examination tool(s)” used herein should be construed to cover any focused charged particle beam device that can be used in examination-related processes. Various types of FCPB devices are mentioned in the background section above. In the context of semiconductor examination, the examination tools 120 include, for example, one or more inspection tools that generate grayscale output images of an examined semiconductor specimen (e.g., by scanning or imaging). An inspection tool is configured to scan a specimen (e.g., an entire wafer, an entire die, or portions thereof) to capture inspection images (typically, at a relatively high-speed and/or low-resolution) for detection of potential defects (i.e., defect candidates).

As mentioned above, inspection tool 120 includes, for example, a Scanning Electron Microscope (SEM). SEM is a type of electron microscope that produces grayscale images of a specimen by scanning it with a focused beam of electrons. The operation of a SEM involves directing a focused beam of high-energy electrons toward a sample surface. This electron beam is generated by an electron gun and then precisely focused and directed using electromagnetic lenses. As the electron beam scans across the surface of the sample, it interacts with the atoms, leading to various outcomes such as the emission of secondary electrons, backscattered electrons, and characteristic X-rays.

The detection of secondary electrons (emitted from atoms near the surface) allows for high-resolution imaging of the sample's topography. Backscattered electrons, which are the primary electrons electromagnetically deviated from the sample atoms, provide information on the composition and contrast, based on atomic number differences within the sample.

Detectors designed for specific types of emissions capture the signals resulting from these interactions. This collected data is then processed to produce a grayscale image, indicating the quantity of electrons captured by the detector. This number of collected electrons varies, depending on the surface topography, composition, or other properties of the sample. Through this process, SEM (Scanning Electron Microscope) tools can generate highly detailed grayscale images of the sample surface at magnification levels unattainable with traditional optical microscopes, providing precise inspection and measurement capabilities during the manufacturing of semiconductor wafers.

In some cases, examination tool 120 further includes a review tool configured to provide a detailed examination of specific areas on a semiconductor wafer, particularly those areas where defects or anomalies have been identified by an inspection tool. It allows for close-up, in-depth analysis of these defects. A review tool is usually configured to inspect fragments of a specimen, one at a time (typically, at a relatively low-speed and/or high-resolution) and generate (GL) images of the reviewed area. By way of example, the review tool can be an electron beam tool, such as a SEM.

The inspection tool and review tool can be different tools located at the same or at different locations, or a single tool operated in two different modes. In some cases, the same examination tool can provide low-resolution image data and high-resolution image data. The resulting image data (low-resolution image data and/or high-resolution image data) can be transmitted-directly or via one or more intermediate systems—to system 101.

Per the illustrated example, computer system 100 comprises processing circuitry 10 configured to execute various processing operations. This includes processing images of a sample (e.g., semiconductor specimen such as a wafer, a die, or parts thereof) generated by an examination tool 120, for example a SEM, performing detailed inspection of the features, including identifying, delineating the boundaries of various features (e.g., contour, shape, or pattern of interest), and measuring the dimensions (e.g., “critical dimensions”) of the sample captured in the images.

Processing circuitry 10 can comprise one or more processors and one or more memories (not shown). In some examples, the processing circuitry is configured to execute several functional modules according to computer-readable instructions implemented on a non-transitory computer-readable memory included in the processing circuitry. These functional modules are hereinafter referred to as being comprised in the processing circuitry.

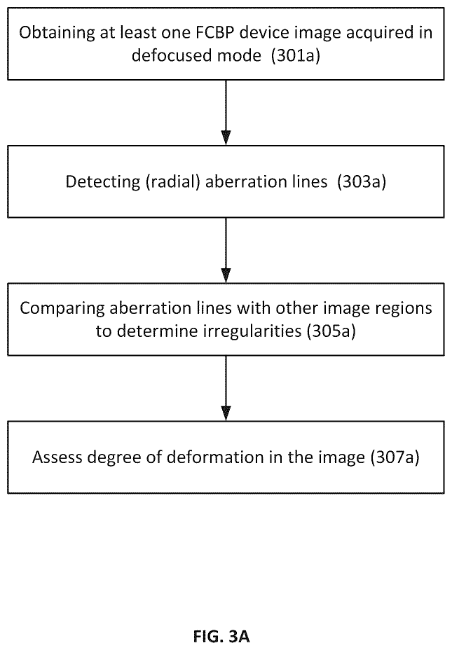

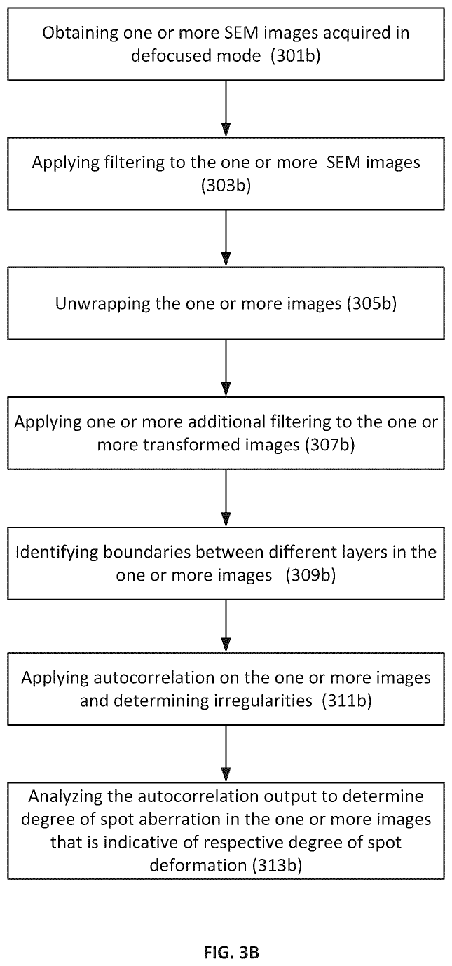

The functional modules include, for example, a spot deformation detection module 12 configured to process output images generated by a FCBP device 120, and determine, using specialized image processing, whether there are aberrations in the FCBP device spot that degrade the output images. Specific operations related to image processing module 10, and particularly spot deformation detection module 12, are described below with reference to FIGS. 3 to 9.

According to some examples, system 100 can comprise or be otherwise operatively connected to a data-storage unit 122. Data storage unit 122 can be configured to store any data necessary for operating system 100 and/or 101, including for example computer software which is loaded during execution of any one of the modules described above, intermediate processing results generated by system 100 and/or 101, FCBP device output images, outputs of spot deformation detection module 12, etc.

In some examples, system 100 and/or system 101 can optionally comprise a user interface 121 to enable user interaction with system 100 and/or system 101. The user interface can include a display device, user interaction devices (e.g., computer mouse and keyboard) and a graphical user interface (GUI) configured to enable, inter alia, user-specified inputs related to system 100 and/or 101. For instance, the user may view on the display the processing results or intermediate processing results, such as, e.g., FCBP device output images, contact hole images, outputs of spot deformation detection module 12, etc.

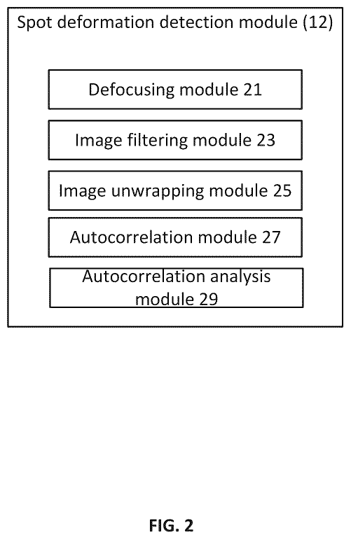

FIG. 2 is a block diagram showing a detailed view of various components of spot aberrations deformation module 12, according to a non-limiting example of the presently disclosed subject matter. These components include Defocusing module 21, Image filtering module 23, Image unwrapping module 25, Autocorrelation module 27 and Autocorrelation Analysis module 29. Operations performed by each of the component listed above are described below with reference to the following figures.

Turning to FIG. 3a, this shows principal operations carried out as part of a spot deformation detection process, in accordance with some examples of the presently disclosed subject matter. Operations described with reference to FIGS. 3a and 3b can be performed for example by spot deformation detection module 12.

As mentioned above, the purpose of the process described herein with reference to FIGS. 3a and 3b is to automatically detect deformations in the spot of a FCPB device. The spot deformation detection process can be executed whenever it is desired to analyze the operation of a FCPB device and detect whether the FCPB device spot is characterized by deformations. The process can be initiated, for example, in response to a user command or automatically in response to another event, such as the detection of a problem (e.g., poor SEM image output), or according to a schedule. In one example, the process is executed ad-hoc for analyzing the image output of a particular FCPB device that provides degraded results, and determining whether the cause is spot deformation. In another example, the process can be executed as part of a maintenance procedure which can be applied from time to time on FCPB devices, e.g., as part of the semiconductor fabrication process for quality control purposes.

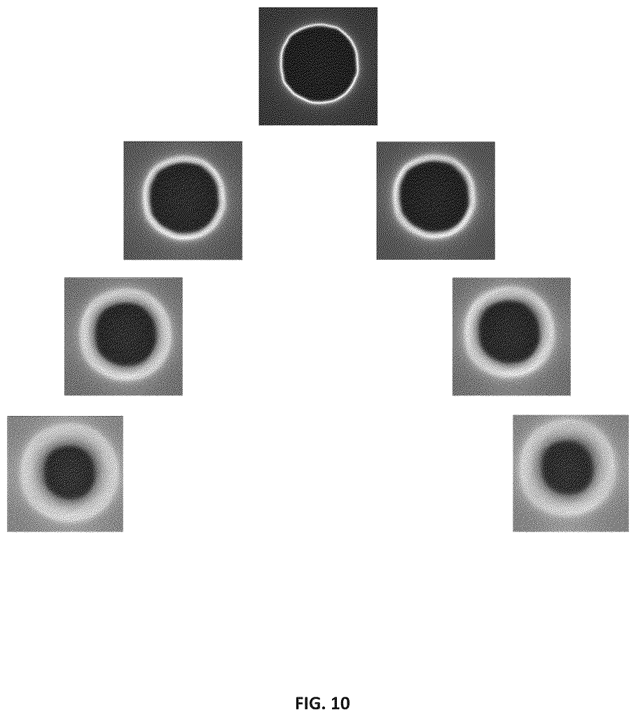

Initially images of rounded features such as contact holes, acquired by the FCPB device while the scanning beam is defocused, are obtained (301a). According to one example, defocusing is controlled by defocusing module 21 in spot deformations detection module 12, being operatively connected to the FCPB device 120 and configured to control its focus for this purpose. In other examples, defocusing can be initiated by direct interaction with the examination tool. FIG. 10 shows examples of images of contact holes that can be used in the spot deformation detection process.

Higher-order aberrations, such as tri-fold or quad-fold aberrations, become more pronounced when the beam is defocused, making them easier to identify. Defocusing the beam, and acquiring images of features such as holes, can assist in revealing aberrations. When the spot is symmetrical (generally assuming a circular spot), the resulting image of a circular feature will be uniformly blurred without any directional bias. However, if the spot is deformed, the image may display non-uniform smearing. An elliptical or asymmetrical spot will cause the image of a circular feature to exhibit lighter lines with radial patterns around the hole. These patterns (referred to herein as “radial aberration lines”) indicate the presence of astigmatism or other higher-order aberrations.

Radial aberration lines are detected (303a). Various techniques can be applied for identifying such radial aberration lines. For example, image processing techniques such as edge detection (e.g., using gradients) and Hough Transform may be used. As further described below with reference to FIG. 3b, the presently disclosed subject matter includes a more streamlined approach for detecting radial aberration lines in the image.

Intensities of each radial aberration line in the image are determined to analyze the aberration lines and detect irregularities (305a). In some examples, pixels values of background lines and aberration lines are summed, and the summed values are compared to determine irregularities. In some examples, intensity variations between aberration lines can be analyzed to determine periodicity. The contrast between radial aberration lines and other parts of the image or reference lines established within the image can be determined to assess the degree of aberrations in the image which is indicative of spot deformation (307a).

FIG. 3b is a flowchart showing details of a particular example disclosed herein of a spot deformation detection process.

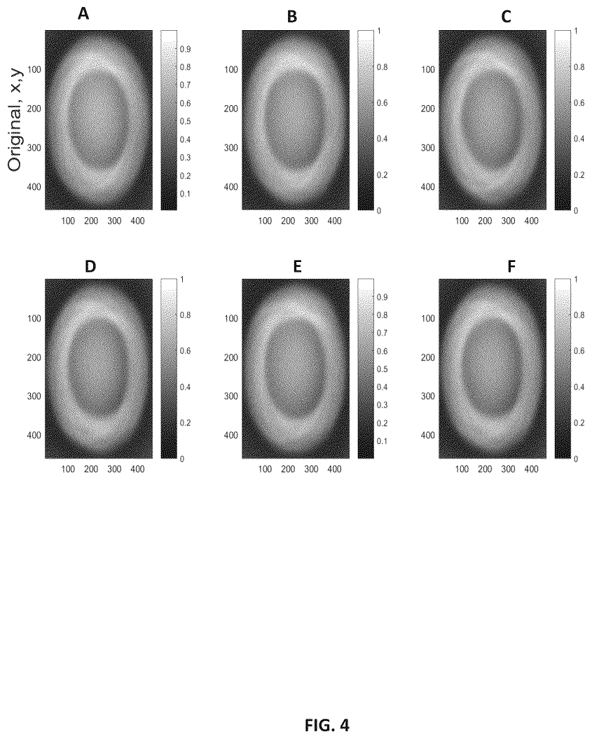

As explained above with respect to FIG. 3a, initially, images of features such as holes, acquired by the SEM while the beam is defocused, are obtained (301b). FIG. 4 shows an example of six different raw SEM images of a contact hole scanned in defocused conditions. As explained above, defocusing enhances aberrations that result from spot deformation. Images in FIG. 4 are symmetric along x and y, with 400 pixels along both axes. Images of the scanned contact hole are characterized by a dark circular center resulting from the depth of the hole and the way electrons are absorbed or scattered within this region and a lighter circumference, indicating the interaction of the SEM's electron beam with the material's surface at the perimeter of the hole. This contrast helps to delineate the boundaries of the contact hole clearly.

Radial aberration lines spiraling around the circumference of the contact hole, resulting from spot deformation, can be seen to varying degrees in the different SEM images A to F. As mentioned above, these lines highlight the presence of astigmatism or some other higher-order aberration in the spot.

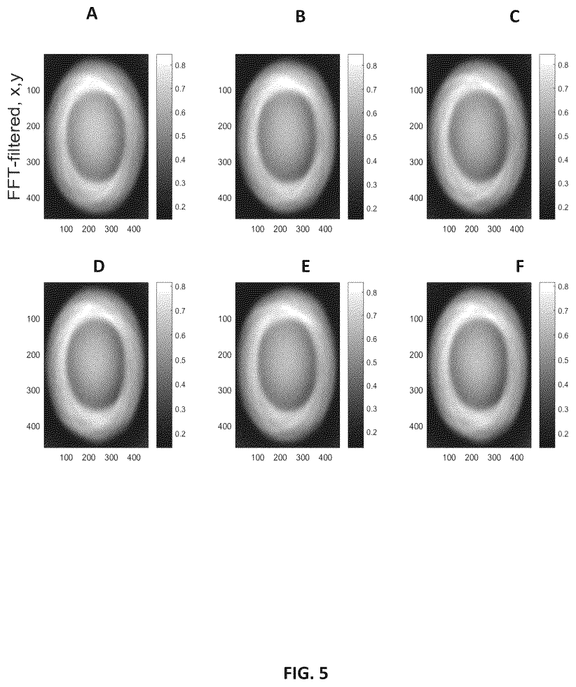

Denoising is applied on the image (or images) to remove noise and sharpen the image (303b). This step is important due to the high noise and low SNR, which are common in defocused SEM images. One non-limiting example of noise filtration involves the application of a Fast Fourier Transform (FFT) by transforming the image from the spatial domain to the frequency domain. In the frequency domain, noise frequencies can be identified and selectively removed. By applying the inverse FFT, the image is reconstructed in the spatial domain with reduced noise, resulting in a sharper and clearer image (deblurred). This process enhances the image quality by eliminating unwanted high-frequency noise and preserving important details. According to one example, denoising is performed by image filtering module 23. In some examples, image filtering module 23 uploads the filtering parameters that include the frequencies that should be removed from the computer storage and applies them during filtering. FIG. 5 shows the images in FIG. 4 following denoising.

According to some examples, the round shape of the hole (annular donut-like shape) is transformed into a rectangular shape (an operation known as “unwrapping”) to enable further processing of the data for determining irregularities (305b; e.g., by image unwrapping module 25). One technique for accomplishing this involves using polar coordinates r and ϑ to convert each point on the donut-like shape into corresponding Cartesian coordinates, thereby re-mapping the donut into a rectangular grid.

Transformation from polar to Cartesian coordinates requires a reference point, which is the center of the inner circle in the donut-like shape. This ensures accurate mapping of each point from the polar coordinates (r, ϑ) to Cartesian coordinates (x, y). Accordingly, the center of the inner circle of the donut-like shape is determined. Various techniques known in the art can be used for this purpose.

One example of a technique that can be used for determining the centroid of the donut-like shape involves calculating image moments. First, the image is converted to a binary format, where the shape is represented by white pixels, and the background by black pixels. The zeroth moment (M₀₀), representing the area, is calculated by summing all white pixels. The first moments (M₁₀ and M₀₁) are determined by summing the x and y coordinates of the white pixels, respectively. The centroid coordinates (x̅, y̅) are then found by dividing the first moments by the zeroth moment. This method enables to accurately locate the center of a shape, facilitating precise transformations, as further described below.

Another example of a technique for determining the centroid of a donut-like shape is spatial averaging, which involves summing the x and y coordinates of all white pixels and dividing by the total number of white pixels to find the mean coordinates.

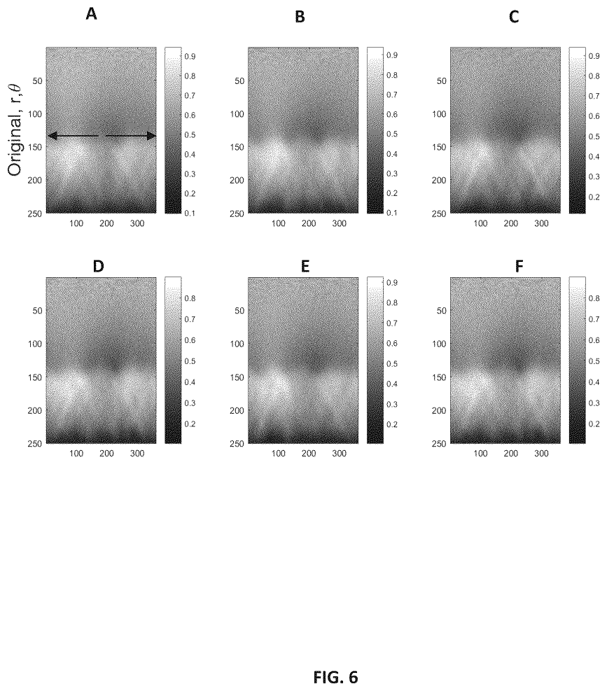

Once the centroid has been calculated, a coordinate transformation is applied to obtain transformed images. FIG. 6 shows the six images following unwrapping. These images illustrate the conversion of the donut-like shape into the Cartesian plane, where the donut-like shape is spread along the x-axis, with the lower part near the x-axis representing the outer edge of the donut. This process results in the radial aberration lines being converted into straight (e.g., diagonal) lines projected onto the Cartesian coordinate system. While uniform interpolation along both the x and y axes would produce an angle of 45 degrees, achieving exactly 45 degrees is not a prerequisite.

The Applicant found that in about 85% of observed cases, the aberration lines exhibit periodicity following unwrapping. This periodicity often results from particular polynomial development modes or a particular combination of modes, such as those described by Zernike polynomials. In some cases, after removing 2-symmetry deformation using stigmators, the strongest remaining element is the 3-symmetry, i.e., a 3rd order aberration showing threefold symmetry patterns. These patterns, when analyzed in the Cartesian plane, can create complex periodic distributions which can manifest as nine distinct periodically distributed lines.

In view of the periodicity, it can be assumed that in most cases the lines' frequency is constant, i.e., is periodic as well. This assumption implies that in most cases the lines will be uniformly disposed on the Cartesian coordinate system, with a consistent pattern and spacing between them.

The unwrapping simplifies the analysis and processing of circular features within the coordinate system, making the data more manageable and comparable within a standard 2D grid framework. More specifically, by transforming radial aberration lines into uniformly disposed lines on the Cartesian plane, it effectively identifies such lines in the image and enables further processing of these lines to assess the degree of their irregularities, as further explained below.

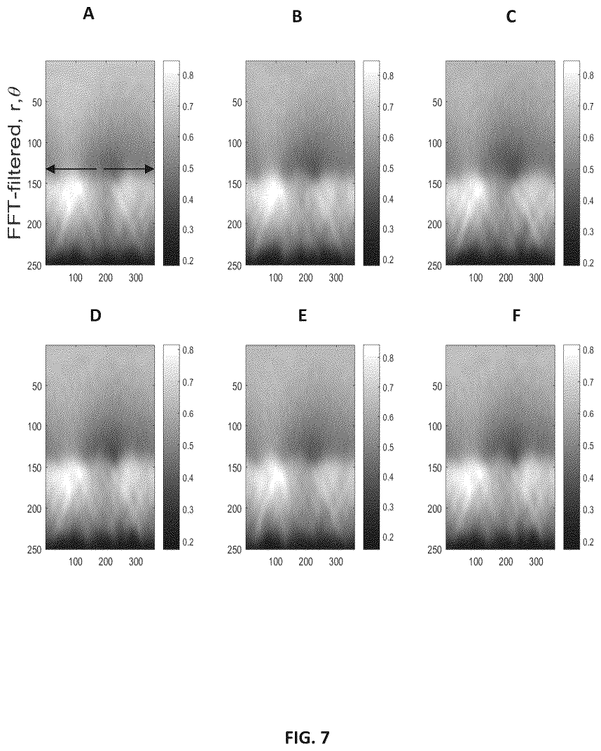

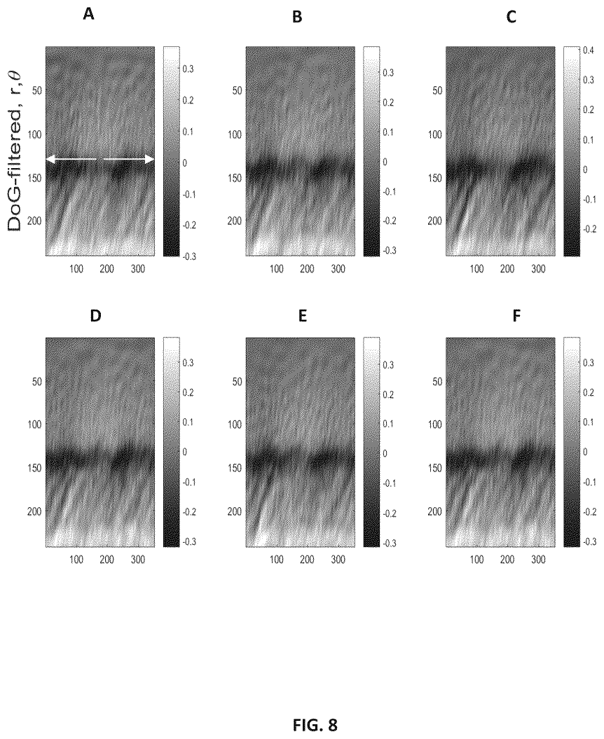

According to some examples, additional denoising is applied following the transformation (unwrapping) into Cartesian coordinate system (307b). This can be accomplished for example by applying FFT as before, or by some other filtering technique. In some examples additional filtering can be applied on the images to improve sharpness of the results. As mentioned above, the importance of denoising is due to the noisy characteristic of the images. In some examples, filtering is executed by image filtering module 23. FIGS. 7 and 8 show the images following denoising and sharpening, respectively.

Image processing may be applied to determine the boundaries between different layers in the images, specifically the transition points between the donut shape and the internal hole at the center on one side (marked by the black arrows in plot A in FIG. 6), and the background on the other side (located at the bottom of the plot) (block 309b).

In some examples, to determine irregularities in the radial direction, autocorrelation is applied on the images of the transformed donut-like shape (311b; e.g., by autocorrelation module 27).

Pixel intensity values are summed and/or averaged along lines in the images to obtain a set of 1-D signals, each representing the intensity variations along a specific line. Autocorrelation is applied on the 1-D signals. Constructive interference is observed when the aberration lines (e.g., bright lines in the image) are in-phase (max score), and destructive interference is observed when the lines are out of phase (minimal score). The stronger the aberration, the stronger the variation will be between the in-phase and out-of-phase calculation.

The use of unwrapping followed by autocorrelation in the spot deformation detection process, as disclosed herein, simplifies the detection and assessment of aberrations caused by spot deformation in a streamlined fashion. This approach eliminates the need to initially identify the lines, as the detection of radial aberration lines is a direct byproduct of the unwrapping and autocorrelation.

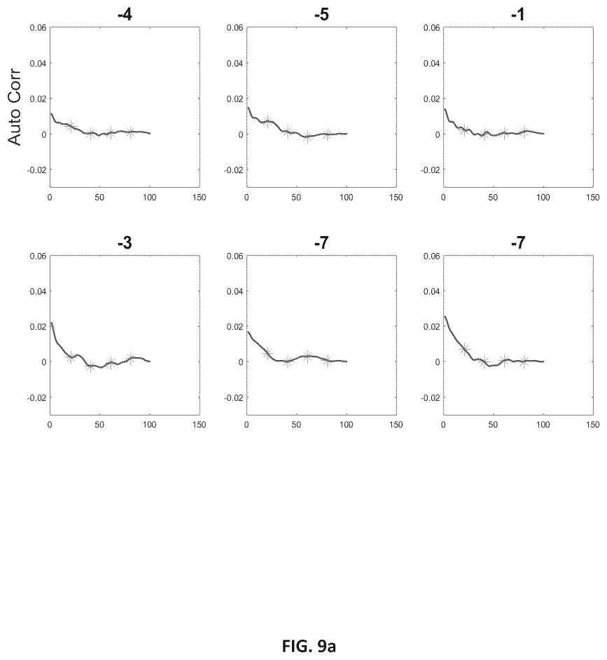

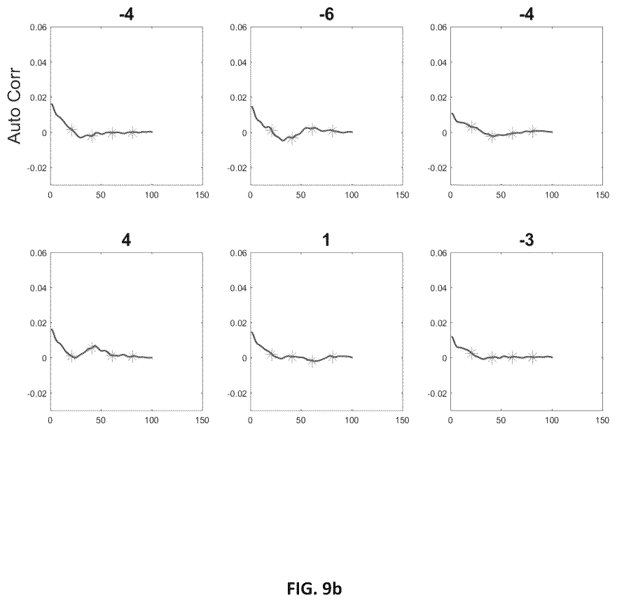

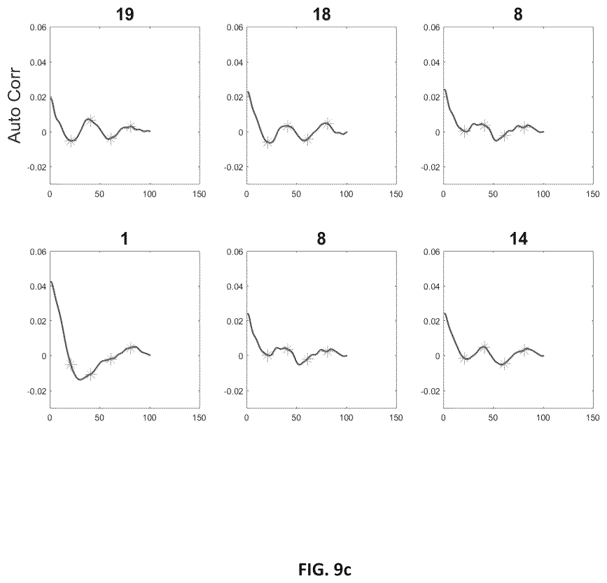

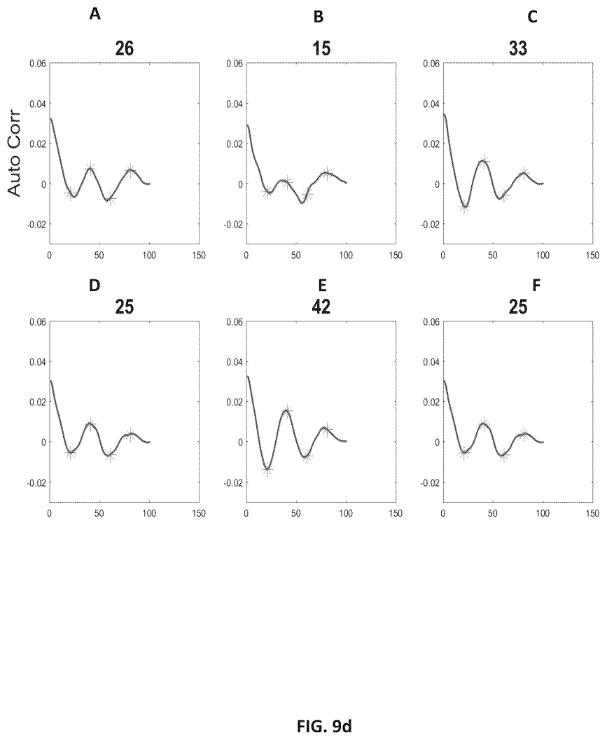

Each one of FIGS. 9a to 9d shows a group of 6 graphs (plots A to F), each group generated based on 6 corresponding SEM contact hole images. Each one of the graphs in each image depicts autocorrelation of a respective contact hole image plotted on a Cartesian coordinate system. This visualization demonstrates how autocorrelation reveals the periodic structures and irregularities within an image.

The X-axis in each graph represents the lag, or the shift, applied to the original image, and the Y-axis (autocorrelation) represents the correlation value at each lag. The plot shows the highest peak at lag 0, indicating perfect correlation with itself. The periodic peaks indicate lags where there are large differences, correlating with irregularities in the image. Specifically, these peaks correspond to the radial lines found in the SEM image, which are converted into straight lines in the Cartesian plane. The greater the undulation of the peaks, the greater the effect of the aberrations. In general, where no aberrations are present, an exponential-like decay is observed, while in case aberrations exist, a highly oscillatory graph is observed. Higher peaks with higher amplitudes in the autocorrelation plot reflect more significant irregularities in the image, indicating stronger or more pronounced aberrations. The greater the amplitude of the peaks, the greater the respective irregularities. Conversely, the more diffuse parts of the curve represent the presence of random noise. Therefore, the peaks in the autocorrelation plot highlight the irregularities due to radial aberration lines, while the more diffuse, lower values, correspond to random noise.

Looking at the six graphs in FIG. 9d, graph B corresponds to the image with the least degree of aberrations, and graph E corresponds to the image with the highest degree of aberrations from all images.

Following autocorrelation, the autocorrelation output can be analyzed to determine peaks in the graph and their amplitude, and determine, based on these values, the severity of the aberrations in the original SEM image (313b). For example, a dedicated module (autocorrelation analysis module 29) in spot deformations detection module 12 can be configured to analyze the autocorrelation output and determine whether it is indicative of aberrations, and to which degree.

Each of one of the images 9a to 9d shows scores labeled at the top of each of the six autocorrelation plots in the image. These scores are calculated based on the difference between the sums of the highest peaks and the lowest troughs in the autocorrelation function (ACF) plots. The scores offer a quantitative measure of irregularities observed in the plot, and are therefore indicative of the degree of aberration which is indicative, in turn, of the degree of spot deformation.

In this example, higher scores signify a greater difference between the high peaks and low troughs, indicating more significant aberrations in the SEM spot analysis. Conversely, lower scores indicate a smaller difference, suggesting fewer or less pronounced aberrations. For example, plot E in FIG. 9d, with a score of 42, demonstrates a substantial degree of aberration, while plot B in FIG. 9d, with a score of 15, shows a lesser degree of aberration. This scoring method allows for a straightforward assessment and comparison of the degree of aberration across different SEM spot analyses. Notably, scores with negative values result from noise in the data.

One or more threshold values can be established to differentiate between varying degrees of aberration. These threshold values can be adjusted according to the quality requirements of different clients. For instance, clients with stricter quality demands, requiring fewer aberrations in the image, may specify more stringent thresholds. FIGS. 9a to 9d exemplify four classes of SEM imaging quality, each associated with a different threshold value, demonstrating how different levels of quality output correspond to varying degrees of aberration and respective deformation of the spot.

While certain examples of the present disclosure refer to a processing circuitry being configured to perform the above recited operations, the functionalities/operations of the aforementioned functional modules can be performed by the one or more processors in the processing circuitry in various ways. By way of example, the operations of each module can be performed by a specific processor, or by a combination of processors. The operations of the various functional modules, such as processing the examination/inspection image, and performing defect examination, etc., can thus be performed by respective processors (or processor combinations), while, optionally, these operations may be performed by the same processor. The present disclosure should not be limited to being construed as one single processor always performing all the operations. Furthermore, any reference made in the specification or claims to a single processing circuitry should be interpreted to optionally include multiple processing circuitries.

Those versed in the art will readily appreciate that the teachings of the presently disclosed subject matter are not bound by the system illustrated in FIG. 1. Each system component and module in FIG. 1 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 1.

Each component in FIG. 1 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

The system illustrated in FIG. 1 can be implemented in a distributed computing environment, in which one or more of the aforementioned components and functional modules shown in FIG. 1 can be distributed over several local and/or remote devices. By way of example, the examination tool 120 and the system 101 can be located at the same entity (in some cases hosted by the same device) or distributed over different entities, each located at a different location.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

It should be further noted that in some examples at least some of examination tools 120 and/or storage unit 122 and/or UI 121 can be external to system 101 and operate in data communication with systems 101 over a suitable communication link. System 101 can be implemented as stand-alone computer(s) to be used in conjunction with the examination tools, and/or with the additional examination modules as described above. Alternatively, the respective functions of system 101 can, at least partly, be integrated with one or more examination tools 120, thereby facilitating and enhancing the functionalities of the examination tools 120.

Unless specifically stated otherwise, as apparent from the above discussions, it is appreciated that, throughout the specification, discussions utilizing terms such as “obtaining”, “detecting”, “comparing”, “assessing”, “applying”, or the like, include an action and/or processes of a computer that manipulate and/or transform data into other data, said data represented as physical quantities, e.g. such as electronic quantities, and/or said data representing the physical objects.

The terms “computer”, “computer system”, “computer device”, “computerized device” or the like used herein, should be expansively construed to include any kind of hardware-based electronic device with one or more data processing circuitries. Each processing circuitry can comprise, for example, one or more processors operatively connected to computer memory, capable of executing stored instructions to perform the operations described herein.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a graphics processing unit (GPU), a network processor, or the like. The one or more processors are configured to execute instructions for performing the operations and steps discussed herein.

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately, or in any suitable sub-combination.

In embodiments of the presently disclosed subject matter, fewer, more and/or different stages than those shown in FIGS. 3a and 3b may be executed. In embodiments of the presently disclosed subject matter, one or more stages illustrated in the figures may be executed in a different order, and/or one or more groups of stages may be executed simultaneously.

It will also be understood that the system according to the presently disclosed subject matter may be a suitably programmed computer. Likewise, the presently disclosed subject matter contemplates a computer program being readable by a computer for executing the method of the presently disclosed subject matter. The presently disclosed subject matter further contemplates a machine-readable (e.g., non-transitory) memory tangibly embodying a program of instructions executable by the machine for executing the method of the presently disclosed subject matter.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

1. A computer-implemented method of detecting spot deformation in a Focused Charged Particles Beam (FCPB) device, comprising:
obtaining an image of a circular feature of a semiconductor specimen generated by the FCPB device while defocused;
detecting radial aberration lines in the image;
comparing between summed intensities of the radial aberration lines to determine irregularities; and
assessing a degree of spot deformation based on the irregularities.

2. The computer-implemented method of claim 1, wherein the image includes a circular donut-like shape comprising an inner circular region bounded by a circumference, the inner circular region and the circumference being rendered in contrasting colors, with one being lighter than the other; wherein detecting radial aberration lines comprises: unwrapping the circular donut-like shape, thereby transforming the radial aberration lines into a plurality of straight lines uniformly projected onto Cartesian coordinates.

3. The computer-implemented method of claim 1, wherein the comparing between summed intensities of the radial aberration lines comprises: applying autocorrelation to the radial aberration lines and detecting periodic peaks that indicate respective periodic irregularities in the image; wherein a greater amplitude of the peaks correlates with a greater respective irregularity, indicating spot deformation.

4. The computer-implemented method of claim 2, wherein the comparing between summed intensities of the radial aberration lines comprises: applying autocorrelation to the plurality of straight lines and detecting periodic peaks that indicate respective periodic irregularities in the image; wherein a greater amplitude of the peaks correlates with a greater respective irregularity, indicating spot deformation.

5. The computer-implemented method of claim 4 wherein the feature is a contact hole.

6. The computer-implemented method of claim 2 comprising, determining a centroid of the donut-like shape prior to unwrapping of the donut-like shape.

7. The computer-implemented method of claim 1 further comprising applying one or more denoising processes to the image and/or its derivatives.

8. The computer-implemented method of claim 1 comprising generating the image by scanning the feature while a scanning beam/lens of the FCPB device is defocused.

9. The computer-implemented method of claim 4, wherein assessing the degree of spot deformation comprises: calculating a score based on a difference between high autocorrelation peak values and low autocorrelation trough values, wherein higher scores correlate with more significant deformation of the spot.

10. The computer-implemented method of claim 1, wherein the FCPB device is a Scanning Electrons Microscope (SEM).

11. A computer system configured and operable to detect spot deformation in a Focused Charged Particles Beam (FCPB) device, the system comprising at least one processing circuitry configured to:
obtain an image of a circular feature of a semiconductor specimen generated by the FCPB device while defocused;
detect radial aberration lines in the image;
compare between summed intensities of the radial aberration lines to determine irregularities; and
assess a degree of spot deformation based on the irregularities.

12. The computer system of claim 11, wherein the image includes a circular donut-like shape with an inner circular region bounded by a circumference, the inner circular region and the circumference being rendered in contrasting colors, with one being lighter than the other; wherein the at least one processing circuitry is configured for detecting radial aberration lines to: apply unwrapping to the circular donut-like shape, thereby transforming the radial aberration lines into a plurality of straight lines uniformly projected onto a Cartesian coordinates.

13. The computer system of claim 11, wherein the at least one processing circuitry is configured for comparing between summed intensities of the radial aberration lines to apply autocorrelation to the radial aberration lines and detect periodic peaks that indicate respective periodic irregularities in the image; wherein a greater amplitude of the peaks correlates with a greater respective irregularity, indicating deformation of the spot.

14. The computer system of claim 12, wherein the at least one processing circuitry is configured for comparing between summed intensities of the radial aberration lines to apply autocorrelation to the plurality of straight lines, and detecting periodic peaks that indicate respective periodic irregularities in the image; wherein a greater amplitude of the peaks correlates with a greater respective irregularity, indicating deformation of the spot.

15. The computer system of claim 14 wherein the feature is a contact hole.

16. The computer system of claim 11, wherein the at least one processing circuitry is configured to apply one or more denoising processes on the image and/or its derivatives.

17. The computer system of claim 11 further comprising the FCPB device that is configured to generate the image by scanning the feature while a scanning beam/lens of the FCPB device is defocused.

18. The computer system of claim 14, wherein the at least one processing circuitry is configured for assessing the degree of spot deformation to calculate a score based on a difference between high autocorrelation peak values and low autocorrelation trough values, wherein higher scores correlate with more significant deformation in the spot.

19. The computer system of claim 11 wherein the FCPB device is a Scanning Electrons Microscope (SEM).

20. A non-transitory computer readable storage medium tangibly embodying a program of instructions that, when executed by a computer, cause the computer to perform a method of detecting spot deformation in a Focused Charged Particles Beam (FCPB) device, comprising:
obtaining an image of a circular feature of a semiconductor specimen generated by the FCPB device while defocused;
detecting radial aberration lines in the image;
comparing between summed intensities of the radial aberration lines to determine irregularities;
assessing a degree of spot deformation based on the irregularities.
